(19) United States
(12) Patent Application Publication
(10) Pub. No.: US 2025/0182306 A1
(43) Pub. Date: Jun. 5, 2025

(54) DIFFEOMORPHIC MR IMAGE REGISTRATION AND RECONSTRUCTION

(71) Applicant: Hyperfine Operations, Inc., Guilford, CT (US)

(72) Inventors: Neel Dey, Guilford, CT (US); Jo Schlemper, Guilford, CT (US); Seyed Sadegh Mohseni Salehi, Guilford, CT (US); Li Yao, Guilford, CT (US); Michal Sofka, Guilford, CT (US)

(73) Assignee: Hyperfine Operations, Inc., Guilford, CT (US)

(21) Appl. No.: 18/610,923

(22) Filed: Mar. 20, 2024

Related U.S. Application Data
(63) Continuation of application No. PCT/US22/44286, filed on Sep. 21, 2022.
(60) Provisional application No. 63/246,652, filed on Sep. 21, 2021.
(60) Provisional application No. 63/313,234, filed on Feb. 23, 2022.

(51) Int. Cl. G06T 7/38; G06T 7/33

(52) U.S. Cl. CPC G06T 7/38; G06T 7/337; G06T 2207/10088; G06T 2207/20081; G06T 2207/20084; G06T 2207/30016

(57) ABSTRACT

Some implementations relate to methods, systems, and computer-readable media for medical imaging. A method includes providing as input to the neural network, a first image and a second image, wherein the first image and the second image are reconstructed from a fast spin echo (FSE) magnetic resonance (MR) imaging sequence, determining, using the neural network, a dense displacement field based at least on the first image and the second image, obtaining, using the neural network, a transformed image based on the first image and the dense displacement field, wherein the transformed image is aligned with the second image, computing a registration loss value based on comparison of the transformed image and the second image, and adjusting one or more parameters of the neural network based on the registration loss value.

### CROSS-REFERENCES TO RELATED APPLICATIONS

This application claims the benefit of priority under 35 U.S.C. § 120 as a continuation of PCT Patent Application No. PCT/US2022/044286, filed on Sep. 21, 2022, which claims priority to U.S. Provisional Patent Application No. 63/246,652, entitled “Magnetic Resonance Image Registration Techniques,” filed Sep. 21, 2021, and U.S. Provisional Patent Application No. 63/313,234, entitled “Machine Learning Techniques for MR Image Registration and Reconstruction,” filed Feb. 23, 2022, the contents of each of which are hereby incorporated by reference herein in their entirety.

### TECHNICAL FIELD

Embodiments relate generally to deep learning techniques and medical imaging.

### BACKGROUND

Medical imaging may include the process of acquiring an image or sequence of images of human tissue and/or organs. For example, magnetic resonance (MR) imaging may acquire several MR images of human tissue for diagnostic and other purposes. Some MR imaging devices can be portable devices to enhance patient care in a variety of different settings.

The primary advantage of portable or point-of-care (POC) MR imaging is a low cost apparatus design that provides mobility, stability, and clinically acceptable images in reasonable scan times. If the portable MR apparatus is a low-field apparatus, low signal-to-noise (SNR) ratios may introduce drawbacks in image quality and increased time to acquisition of clinically acceptable images.

To avoid drawbacks associated with low SNR, fast spin echo (FSE) based sequences in which multiple echoes can be combined to increase the SNR may be used. In the presence of system imperfections, however, the even and odd echoes introduce further drawbacks due to uncorrected eddy currents causing differential warping between the two echo sequences.

The background description provided herein is for the purpose of presenting the context of the disclosure. Content of this background section, as well as aspects of the description that may not otherwise qualify as prior art at the time of filing, are neither expressly nor impliedly admitted as prior art against the present disclosure.

### SUMMARY

Aspects of this disclosure are directed to methods, systems, and computer readable media to provide deep learning techniques for rapid, accurate, and clinically acceptable medical imaging.

According to one aspect a computer-implemented method to train a neural network to perform image registration is provided, the method comprising: providing as input to the neural network, a first image and a second image, wherein the first image and the second image are reconstructed from a fast spin echo (FSE) magnetic resonance (MR) imaging sequence; determining, using the neural network, a dense displacement field based at least on the first image and the second image; obtaining, using the neural network, a transformed image based on the first image and the dense displacement field, wherein the transformed image is aligned with the second image; computing a registration loss value based on comparison of the transformed image and the second image; and adjusting one or more parameters of the neural network based on the registration loss value.

Various implementations and embodiments of the computer-implemented method are described.

According to some implementations, determining the dense displacement field comprises: predicting, using the neural network, a stationary velocity field; and integrating, using the neural network, the stationary velocity field to determine the dense displacement field.

According to some implementations, the dense displacement field is a diffeomorphic displacement field.

According to some implementations, the first image is reconstructed from a first set of echoes of the FSE MR imaging sequence, and wherein the second image is reconstructed from a second set of echoes of the FSE MR imaging sequence.

According to some implementations, obtaining the transformed image comprises: applying, with a spatial transform network, the dense displacement field to the first image, wherein the spatial transform network outputs the transformed image.

According to some implementations, computing the registration loss value comprises: minimizing a local normalized cross correlation value based on the transformed image and the second image.

According to some implementations, training the neural network is an unsupervised process.

In another aspect, a device to perform image registration is provided, the device comprising: one or more processors; and a memory coupled to the one or more processors, with instructions stored thereon that, when executed by the processor, cause the one or more processors to perform operations comprising: providing a first image and a second image as input to a trained neural network, wherein the first image and the second image are reconstructed from a fast spin echo (FSE) magnetic resonance (MR) imaging sequence; obtaining, as output of the trained neural network, a dense displacement field for the first image; obtaining a transformed image by applying the dense displacement field to the first image with a spatial transform network, wherein corresponding features of the transformed image and the second image are aligned; and outputting the transformed image.

Various implementations and embodiments of the device are described.

According to some implementations, obtaining the dense displacement field comprises: obtaining, using the trained neural network, a stationary velocity field; and integrating, using the trained neural network, the stationary velocity field to determine the dense displacement field.

According to some implementations, the device is a portable low-field MR imaging device having a display device and at least one permanent magnet.

According to some implementations, the first image is reconstructed from a first set of echoes of the FSE MR imaging sequence, and wherein the second image is reconstructed from a second set of echoes of the FSE MR imaging sequence.

According to some implementations, the first set of echoes comprise odd echoes, and wherein the second set of echoes comprises even echoes.

According to some implementations, the first image and the second image are of a human tissue or a human organ.

According to some implementations, outputting the transformed image comprises displaying the transformed image on the display device.

In another aspect, a non-transitory computer-readable medium to train a neural network to perform image registration is provided, the non-transitory computer-readable medium with instructions stored thereon that, when executed by a processor of a server, cause the processor to perform operations, the operations comprising: providing as input to the neural network, a first image and a second image, wherein the first image and the second image are reconstructed from a fast spin echo (FSE) magnetic resonance (MR) imaging sequence; determining, using the neural network, a dense displacement field based at least on the first image and the second image; obtaining, using the neural network, a transformed image based on the first image and the dense displacement field, wherein the transformed image is aligned with the second image; computing a registration loss value based on comparison of the transformed image and the second image; and adjusting one or more parameters of the neural network based on the registration loss value.

Various implementations and embodiments of the non-transitory computer-readable storage medium are described.

According to some implementations, determining the dense displacement field comprises: predicting, using the neural network, a stationary velocity field; and integrating, using the neural network, the stationary velocity field to determine the dense displacement field.

According to some implementations, the first image is reconstructed from a first set of echoes of the FSE MR imaging sequence, and the second image is reconstructed from a second set of echoes of the FSE MR imaging sequence.

According to some implementations, obtaining the transformed image comprises: applying, with a spatial transform network, the dense displacement field to the first image, wherein the spatial transform network outputs the transformed image.

According to some implementations, computing the registration loss value comprises: minimizing a local normalized cross correlation value based on the transformed image and the second image.

According to some implementations, training the neural network is an unsupervised process.

According to yet another aspect, portions, features, and implementation details of the systems, devices, methods, and non-transitory computer-readable media may be combined to form additional aspects, including some aspects which omit and/or modify some or portions of individual components or features, include additional components or features, and/or other modifications; and all such modifications are within the scope of this disclosure.

### BRIEF DESCRIPTION OF DRAWINGS

FIG. 1 is a diagram of an example network environment for medical imaging, in accordance with some implementations.

FIG. 2 is a diagram of an example medical imaging pipeline, in accordance with some implementations.

FIG. 3A is a diagram of an image registration component for medical imaging, in accordance with some implementations.

FIG. 3B is a diagram of an alternative image registration component for medical imaging, in accordance with some implementations.

FIG. 4A illustrates a table of quantitative experimental results of image registration.

FIG. 4B illustrates a comparison of qualitative experimental results of image registration.

FIG. 4C illustrates a comparison of qualitative experimental results of pathology images.

FIG. 5 is a flowchart of an example method of unsupervised training of a neural network, in accordance with some implementations.

FIG. 6 is a flowchart of a method of medical imaging, in accordance with some implementations.

FIG. 7 is a flowchart of a method of image registration using a trained neural network, in accordance with some implementations.

FIG. 8 is a block diagram illustrating an example computing device, in accordance with some implementations.

FIG. 9 is a flowchart of an example method of unsupervised training of a neural network, in accordance with some implementations.

FIG. 10 is a flowchart of a method of medical imaging, in accordance with some implementations.

FIG. 11 is a flowchart of a method of image registration using a trained neural network, in accordance with some implementations.

### DETAILED DESCRIPTION

In the following detailed description, reference is made to the accompanying drawings, which form a part hereof. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented herein. Aspects of the present disclosure, as generally described herein, and illustrated in the Figures, can be arranged, substituted, combined, separated, and designed in a wide variety of different configurations, all of which are contemplated herein.

References in the specification to “some implementations”, “an implementation”, “an example implementation”, etc. indicate that the implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, such feature, structure, or characteristic may be effected in connection with other implementations whether or not explicitly described.

In some aspects, systems and methods are described for deep learning techniques in medical imaging.

Deep learning may be a subset of a broader set of machine learning techniques. For example, machine learning may sometimes be referred to as a type of “artificial intelligence” that involves training a computer to perform particular tasks. Deep learning may typically be based upon artificial neural networks with a form of representative learning, that is, training a computer to provide an output based on an input and adjusting the computer to achieve a better result in the future.

In medical imaging, magnetic resonance imaging devices (e.g., MR imaging devices) are sometimes used to provide views inside of the human body. Portable MR imaging can utilize a low cost apparatus design that provides mobility, stability, and clinically acceptable images in reasonable scan times. If the portable MR apparatus is a low-field apparatus, low signal-to-noise (SNR) ratios may introduce drawbacks in image quality and increased time to acquisition of clinically acceptable images. For example, a low SNR denotes that there may be a small difference between the “signal” and the “noise” within a provided image.

To avoid drawbacks associated with low SNR, fast spin echo (FSE) based sequences may be used. In FSE, multiple “echoes” produced in a single imaging cycle may be combined together to try and increase the SNR. FSE techniques may improve scan times in an MR imaging device, but also sometimes warp even and/or odd echo images if there are any imperfections in the MR imaging device.

This disclosure relates to overcoming the warping so that the FSE techniques may be used to decrease scan times, while still providing high-quality, clinically acceptable images. Overcoming the warping is achieved by training a machine learning model, in this example an artificial neural network, to accurately align even and odd echo images produced by the FSE techniques. The accurately aligned images may be combined together to form the clinically acceptable images with a better SNR and more usefulness. These clinically acceptable images may be used in the diagnosis of diseases, tracking of cancerous growths, and other medical uses.

Hereinafter, example embodiments of the disclosure are described in detail.

According to various implementations described herein, unsupervised learning for a diffeomorphic registration framework that may be applied to register even and odd echo images is described. The framework may be generalized across different contrast including T1-weighted, T2-weighted, fluid attenuated inversion recovery (FLAIR), and diffusion weighted images (DWI).

FSE sequences provide echoes with an improved imaging time compared to typical imaging cycles, but may also introduce differential warping between reconstructed echo images. Through various techniques described herein, the diffeomorphic registration framework may be trained in an unsupervised manner to minimize a loss function. The diffeomorphic registration network may be introduced into a medical imaging pipeline to align even and odd echo images and may provide, as an output, properly aligned output images for post-processing and/or display.

Hereinafter, further details surrounding example embodiments and various aspects of this disclosure are described with reference to the figures.

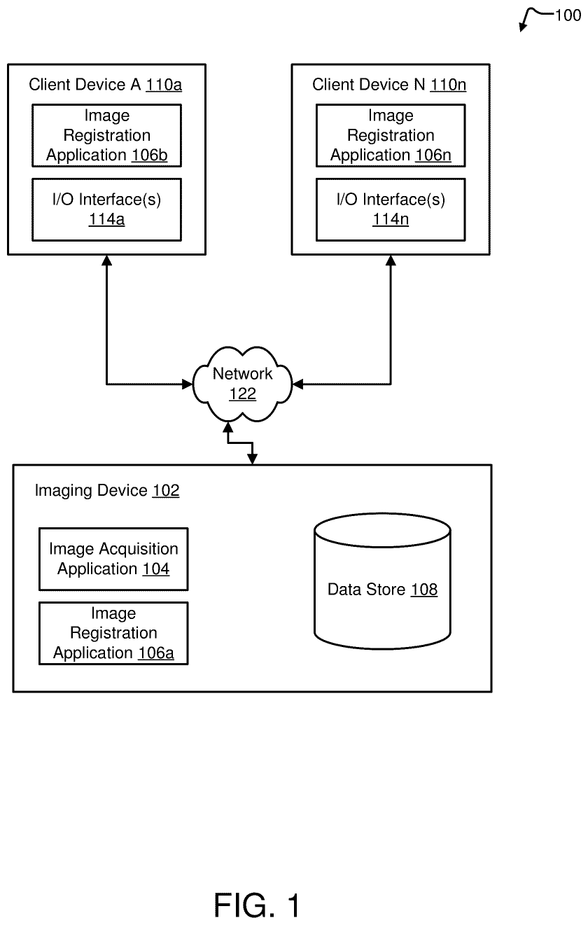

### FIG. 1: System Architecture

FIG. 1 illustrates an example network environment 100, in accordance with some implementations of the disclosure. FIG. 1 and the other figures use like reference numerals to identify like elements. A letter after a reference numeral, such as “110a,” indicates that the text refers specifically to the element having that particular reference numeral. A reference numeral in the text without a following letter, such as “110,” refers to any or all of the elements in the figures bearing that reference numeral (e.g., “110” in the text refers to reference numerals “110a,” “110b,” and/or “110n” in the figures).

The network environment 100 (also referred to as a “system” herein) may include an imaging device 102 and one or more client devices 110, all coupled via a network 122.

The imaging device 102 may include a processor, a memory, and imaging hardware. In some implementations, the imaging device 102 may be an MRI device, a Computed Tomography (CT) device, a Single-Photon Emission Computerized Tomography (SPECT) device, a Positron Emission Tomography (PET) device, or another suitable medical imaging device.

In some implementations, the imaging device 102 may be a portable low-field MR imaging system. In various aspects of the imaging device, the field strength of the MR imaging system may be produced by permanent magnets. In some implementations, the field strength may be between 5 mT and 200 mT. In some implementations, the average field strength may be between 50 mT and 80 mT. In some implementations, the permanent magnets may include a bi-planar permanent magnet.

In various implementations, the imaging device may be portable. In some implementations, the imaging device may weigh less than 1500 lbs, and be movable on casters or wheels. In some implementations, the imaging device may be less than 60 inches tall, 34 inches wide, and fits through most doorways. In some implementations, the imaging device may have a motor to drive one or more wheels to propel the imaging device. In some implementations, the imaging device may have a power supply to provide power to the motor, or the MR imaging system, independent of an external power supply. In some implementations, the imaging device may draw power from an external power supply, such as a single phase electrical power supply, like a wall outlet. In some implementations, the imaging device uses less than 900 W during operation. In some implementations, the imaging device includes a joystick for guiding movement of the imaging device.

In some implementations, the imaging device may comprise a bi-planar permanent magnet, a gradient component, and at least one radio frequency (RF) component configured to receive data.

In some implementations, the imaging device may comprise a base configured to house electronics that operate the imaging device. For example, the base may house electronics including, but not limited to, one or more gradient power amplifiers, an on-system computer, a power distribution unit, one or more power supplies, and/or any other power components configured to operation the imaging device using mains electricity. For example, the base may house low power components, such that the imaging device may be powered from readily available wall outlets. Accordingly, the imaging device can be brought to a patient and plugged into a wall outlet in the vicinity of the patient.

In some implementations, the imaging device may be operated from a portable electronic device, such as a notepad computer, tablet computer, smartphone, etc. For example, a tablet computer may be used to operate the imaging device, and to execute various implementations of image registration methods and sub-methods.

In some implementations, the imaging device may include a safety line guard to demarcate a 5 Gauss line about a perimeter of the imaging device.

In some implementations, the imaging device 102 may be operative to send and receive data to and from the client devices 110 over the network 122. The imaging device 102 may include an image acquisition application 104, an image registration application 106a, and a data store 108.

In some implementations, the image acquisition application 104 may include computer-executable code and/or algorithms operative to acquire medical images, FSE images, and/or other suitable images using the imaging device 102. For example, in one implementation, the image acquisition application 104 may be configured to direct imaging components of the imaging device 102 to transmit energy into or about a human body, to receive energy that has been transmitted about or through the human body, and to reconstruct images therefrom. The reconstructed images may be based upon any suitable imaging technique. In one implementation, the reconstructed images may be based upon a FSE technique applied to a low-field MR imaging device.

In some implementations, the image registration application 106a may include computer-executable code and/or algorithms operative to train a neural network to perform FSE image registration. For example, the image registration application 106a may provide as input to the neural network, a first image and a second image reconstructed from a FSE MR imaging sequence, determine, using the neural network, a dense displacement field based at least on the first image and the second image, obtain, using the neural network, a transformed image based on the first image and the dense displacement field, wherein the transformed image is aligned with the second image, compute a registration loss value based on comparison of the transformed image and the second image, and adjust one or more parameters of the neural network based on the registration loss value.

In some implementations, the image registration application 106a may include computer-executable code and/or algorithms operative to perform FSE image registration. For example, the image registration application 106a may provide a first image and a second image as input to a trained neural network, wherein the first image and the second image may be images reconstructed from a fast spin echo (FSE) magnetic resonance (MR) imaging sequence, obtain, as output of the trained neural network, a dense displacement field for the first image, obtain a transformed image by applying the dense displacement field to the first image with a spatial transform network, wherein corresponding features of the transformed image and the second image are aligned, and output the transformed image. In some implementations the output image may be displayed at the imaging device 102 or at a client device 110.

In some implementations, the image registration application 106a may include computer-executable code and/or algorithms operative to train a neural network to perform FSE image registration. For example, the image registration application 106a may provide as input to the neural network, a first image and a second image reconstructed from a FSE MR imaging sequence, determine, using the neural network, a transformation matrix based at least on the first image and the second image, obtain, using the neural network, a transformed image based on the first image and the transformation matrix, wherein the transformed image is aligned with the second image, compute a registration loss value based on comparison of the transformed image and the second image, and adjust one or more parameters of the neural network based on the registration loss value.

In some implementations, the image registration application 106a may include computer-executable code and/or algorithms operative to perform FSE image registration. For example, the image registration application 106a may provide a first image and a second image as input to a trained neural network, wherein the first image and the second image may be images reconstructed from a fast spin echo (FSE) magnetic resonance (MR) imaging sequence, obtain, as output of the trained neural network, a transformation matrix for the first image, obtain a transformed image by applying the transformation matrix to the first image with a spatial transform network, wherein corresponding features of the transformed image and the second image are aligned, and output the transformed image. In some implementations the output image may be displayed at the imaging device 102 or at a client device 110.

In some implementations, the imaging device 102 may comprise hardware specifically configured to perform neural network computations/processing and/or other specialized hardware configured to perform one or more methodologies described in detail herein. For example, specialized hardware may include machine learning processors and/or graphical processing units (GPU) configured to perform neural network calculations. In some implementations, the imaging device 102 may comprise hardware of a conventional type that, upon executing code described herein, transforms the conventional hardware into specialized hardware configured to perform image registration of FSE images as described herein.

The data store 108 may be a non-transitory computer readable memory (e.g., random access memory), a cache, a drive (e.g., a hard drive), a flash drive, a database system, or another type of component or device capable of storing data. The data store 108 may also include multiple storage components (e.g., multiple drives or multiple databases) that may also span multiple computing devices (e.g., multiple server computers). The data store 108 may be configured to store images, neural network weights, neural network structures, training data, and other suitable data associated with the image registration application 106.

The network 122 may include a public network (e.g., the Internet), a private network (e.g., a local area network (LAN) or wide area network (WAN)), a wired network (e.g., Ethernet network), a wireless network (e.g., an 802.11 network, a Wi-Fi® network, or wireless LAN (WLAN)), a cellular network (e.g., a Long Term Evolution (LTE) network), routers, hubs, switches, server computers, or a combination thereof. Although one network 122 is illustrated, one or more networks 1225 may also be used in some implementations.

The client devices 110 may be computing devices that each may include a memory, a computer processor, input/output interfaces 114, an image registration application 106, and a display. In some implementations, the client devices 110 may be operable to perform some or all of the functions of the image registration application 106, including training. In some implementations, a portion of the image registration application 106 functions may be performed by the client devices 110 while another portion may be performed by the imaging device 102. For example, in some implementations, client devices 110 may be used to train a neural network while imaging device 102 may be used to deploy a trained neural network, or vice versa. Other suitable variations may also be applicable.

In some implementations, image data from image registration application 106a may be transmitted to a client device 110 via physical memory, via network 122, and/or via a combination of physical and/or network communication. For example, some suitable physical memory devices may include flash drives, encrypted flash drives, portable hard drives, compact discs (CD), or other removable media.

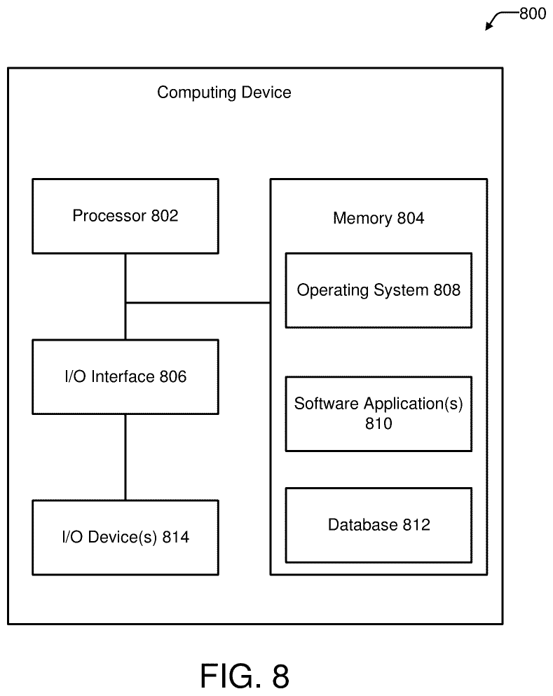

It is noted that several computing components that may be included in each of the imaging device 102 and the client devices 110a-110n are described in detail with reference to FIG. 8.

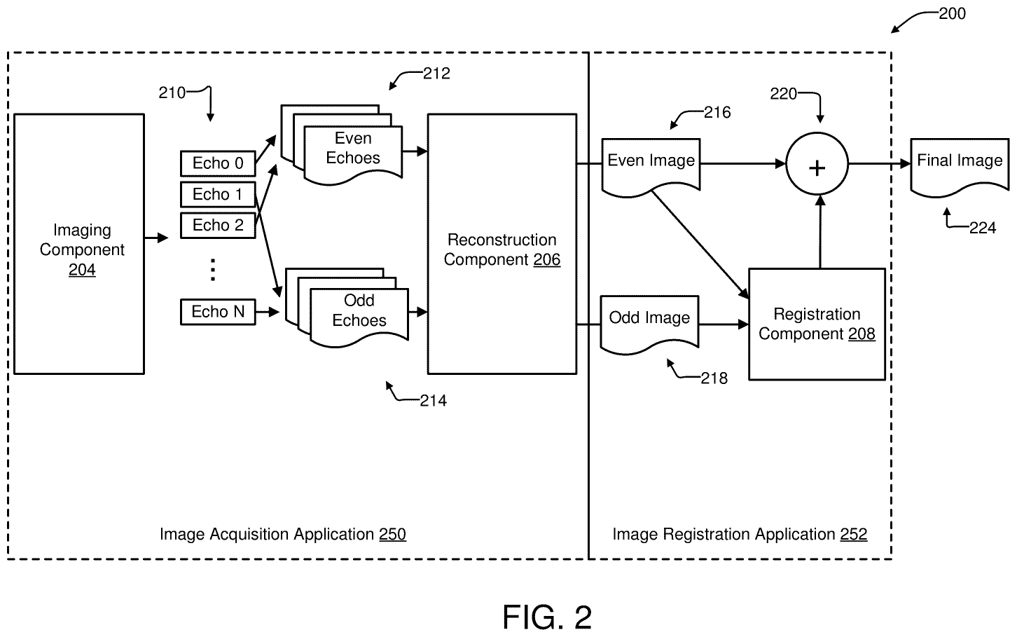

Hereinafter, functions of the image acquisition application 104 and the image registration application 106 are described more fully with reference to FIG. 2.

### FIG. 2: Medical Imaging Pipeline

FIG. 2 is a diagram of an example medical imaging pipeline 200, in accordance with some implementations. The pipeline 200 may be implemented within an imaging device. In some implementations, the pipeline 200 is included in an imaging device such as the imaging device 102. It is noted that portions associated with the image registration application may also be offloaded to one or more client devices, in some implementations.

In some implementations, the imaging pipeline 200 may comprise an image acquisition application 250 and an image registration application 252. In one implementation, the image acquisition application 250 may comprise imaging component or components 204 and a reconstruction component 206. Furthermore, in one implementation the image acquisition application 250 may further comprise a registration component 208. In another implementation, the registration component 208 is included as part of the image acquisition application 250.

Imaging components 204 of the imaging pipeline 200 may include components configured to control a bi-planar permanent magnet (e.g., two permanent magnets arranged in a bi-planar geometry), a gradient component, and at least one radio frequency (RF) component configured to receive data. The received data may include fast train echo (FSE) data including echoes 210 for reconstruction into images 216, 218.

For example, imaging components 204 may provide echoes 210. The image acquisition application 250 may separately group and reconstruct even echoes subset 212 and odd echoes subset 214 from the echoes 210. The grouping may include selecting and acquiring all even echoes to form the subset 212. The grouping may also include selecting and acquiring all odd echoes to form the subset 214.

The image acquisition application 250 may direct the even echoes 212 and the odd echoes 214 to the reconstruction component 206. The reconstruction component 206 may be configured to receive echo data (e.g., individual echoes) and produce a reconstructed image from the received echo data. In some implementations, each illustrated sub-portion of echo data 210 may be used to reconstruct a single image. While a single even image and odd image are illustrated, it should be readily understood that a plurality of even and odd images may be reconstructed from the echo data 210.

The image acquisition application 250 may provide the even image 216 and the odd image 218 to the image registration application 252, in some implementations.

The image registration application 252 may direct the even image 216 and the odd image 218 to the registration component 208 for image registration. The registration component 208 may deform and move the odd image 218 into registration or feature alignment with the even image 216. For example, the registration component 208 may include a trained neural network deployed therein configured to perform image registration. It is noted that the registration component 208 may also be configured to register the even image 216 to the odd image 218, or vice versa, in some implementations.

In some implementations, the registration component 208 may be further configured to combine multiple images, in addition to the even and odd echo images. For example, the registration component 208 may be configured to provide registration of multiple images for motion compensation or other compensation. In these examples, image registration may be performed not only to reduce warping and increase SNR between echoes of a FSE sequence, but also to compensate for patient motion, image artifacts, and other drawbacks. In these examples, the multiple images may be combined into a single, deformed moved image during an image registration process by a trained registration component 208.

The deformed moved image (output from the registration component 208) may be combined with the even image 216 at combination component 220. For example, the combination component 220 may be configured to combine the even image 216 with the deformed moved image output from the registration component 208 and create a final image 224.

In some implementations, the combination component 220 may include a signal averaging component configured to combine the even image 216 with the deformed moved image. Signal averaging may include signal averaging of complex-valued MR images based upon magnitude or complex-base.

In some implementations, the combination component 220 may be configured to combine the even image 216 with the deformed moved image based on simple summation.

In some implementations, the combination component 220 may be configured to combine the even image 216 with the deformed moved image based on solving a regularized optimization problem. For example, the combination may be done by first mapping (back) the even/odd images to “multi-coil” images (e.g., from a multi-coil array) by applying a coil map (e.g., n “maps” of the same dimensionality as the image that describes the spatial weighting of the image). The combination may be completed by solving a regularized optimization problem of: argminₓ:wt₁*∥xₑᵥₑₙ−x∥+wt₂*∥x_{odd}−x∥+R(x), where R is a regularization function, such as sparsity, low-rank, etc. In this particular example, a low-rank optimization method may be apparent. However, other optimization methods may also be applicable in some implementations.

The final image 224 may be the combination of the two input images 216 and 218, and may undergo post-processing and other techniques prior to medical use. Some post-processing techniques may include de-noising, distortion correction, homogeneity correction, and other techniques.

As described, the pipeline 200 may acquire images and process the images, using a trained neural network deployed at the registration component 208.

Hereinafter, training of a registration component and an associated neural network are described in detail.

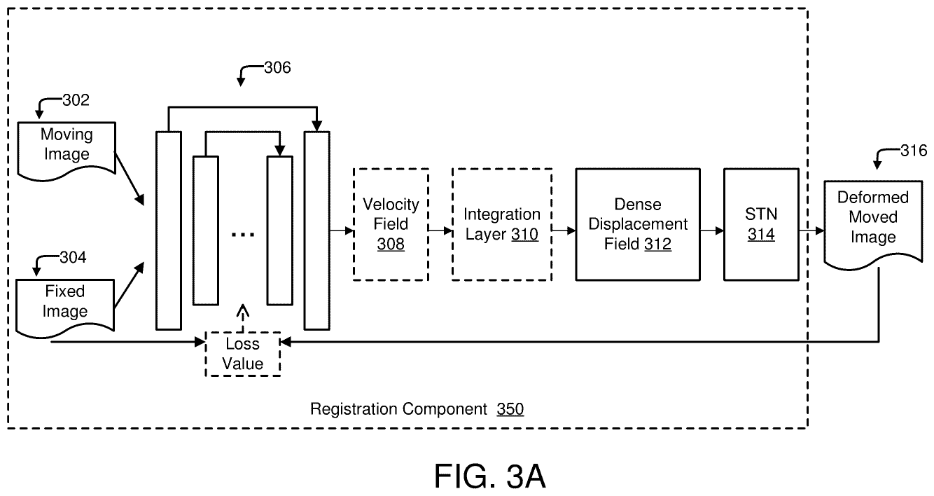

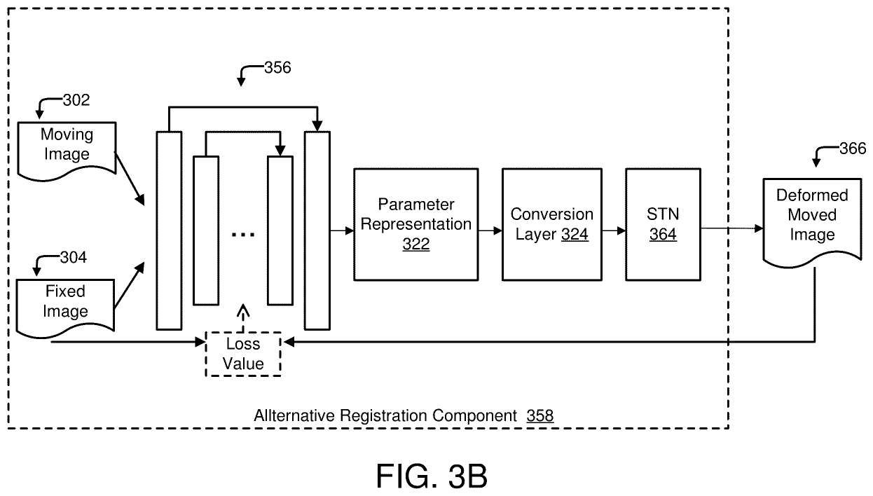

### FIG. 3A: Image Registration Component and Training

FIG. 3A is a diagram of an image registration component 350 for medical imaging, in accordance with some implementations. The registration component 350 may be included as a portion of an image registration application deployed at an imaging device, client device, or a combination thereof.

The registration component 350 may comprise a neural network 306 and a spatial transform network (STN) 314. The neural network 306 may be any suitable neural network that may undergo unsupervised training to align and register a moving image 302 to a stationary (or fixed) image 304. In some implementations, the neural network 306 may be a convolutional neural network (CNN). In some implementations, the neural network 306 may be a Unet-style VoxelMorph network where a convolutional neural network may be trained to align the moving image 302 to the fixed image 304.

During initial training, the neural network 306 may receive the moving image 302 and the fixed image 304 as inputs. Thereafter, a velocity field 308 may be estimated or predicted. For example, the velocity field 308 may be a stationary velocity field.

The registration component 350 may integrate the predicted velocity field 308 from t=[0,1] (i.e., using integration layers 310), to obtain a dense displacement field. For example, by scaling and squaring layers of the stationary velocity field 308, with the integration layer 310, a dense displacement field 312 may be obtained. In some implementations, the dense displacement field 312 may be a diffeomorphic displacement field.

Generally, the goal of training the registration network may be to obtain a dense displacement field such that argmin_{ϕ} [symbol] (xₑᵥₑₙ, x_{odd}(ϕ). The dense displacement field may be represented as ϕ=f_{ϕ}((xₑᵥₑₙ, x_{odd})), where ϕ is the displacement field, xₑᵥₑₙ represents the even echo or fixed image, and x_{odd} represents the odd echo or moving image.

The registration component 350 may be configured to compute a registration loss value based upon the input images and output image such that local normalized cross correlation (LNCC) is minimized as shown in Equation 1:

$$ℒ : NCC ( x , y ) = \frac{{\sum }_{i} {( ( {x}_{i} - {μ}_{x} ) ( {y}_{i} - {μ}_{y} ) )}^{′} 2}{{\sum }_{i} {( {x}_{i} - {μ}_{x} )}^{′} 2 {\sum }_{i} {( {y}_{i} - {μ}_{y} )}^{′} 2} \qquad Equation 1$$

In Equation 1, x and y are local square windows in which the cross correlation is calculated. LNCC over all local windows in the image is averaged to yield [symbol] .

Other loss functions may also be used. Some example loss functions that may be applicable to various implementations include L1, L2, L1+L2, modality independent neighborhood descriptor (MIND), Normalized Gradient Fields (NGF), and/or image feature-based loss functions.

The L1 loss function may also be known as least absolute deviations and may be used to minimize the error of the sum of all the absolute differences between a true value and a predicted value.

The L2 loss function may also be known as least square errors. A L2 loss function may be used to minimize the error that is the sum of the squared differences between the true value and the predicted value.

The MIND loss function may aim to extract a distinctive structure in a local neighborhood, which may be presented across modalities, and may be based on the similarity of small image patches within one image.

The NGF loss function may be based on the gradients of the transformed image and reference images (e.g., input images or even/odd echoes).

An image feature-based loss function may include any suitable loss function based on image features, such as, for example, L1 loss based upon image gradient.

In one implementation, the neural network 306 may be trained for all contrasts including T1-weighted, T2-weighted, fluid attenuated inversion recovery (FLAIR), and diffusion weighted images (DWI). For data augmentation in training, a random translation of #3 pixels, anisotropic scaling in range (0.9, 1.2), random flipping, and/or a Gaussian noise up to standard deviation σ=0.03 may also be implemented.

The trained neural network 306 may be deployed for image registration with an imaging device. For example, the registration component 350 may provide the dense displacement field 312 as input to the STN 314, which may also receive the moving image 302. The STN 314 may apply the dense displacement field 312 to the moving image 302 and may output a deformed moved image 316. The trained neural network 306 may provide a dense displacement field 312 as an output for registering the moving image 302 to the fixed image 304.

It is noted that in some implementations, the velocity field 308 and integration layer 310 may be omitted. In these and other implementations, the neural network 306 may be trained to output the diffeomorphic displacement field 312 directly.

It is also noted that in some implementations, the velocity field 308, integration layer 310, and displacement field 312 may be omitted and/or replaced with a parameter representation output directly from the neural network 306 and a conversion layer. For example, FIG. 3B illustrates an alternative image registration component, in accordance with some implementations.

### FIG. 3B: Alternative Image Registration Component and Training

FIG. 3B is a diagram of an alternative registration component 358 for medical imaging, in accordance with some implementations. The alternative registration component 358 may be included as a portion of an image registration application deployed at an imaging device, client device, or a combination thereof.

The alternative registration component 358 may comprise a neural network 356 and a spatial transform network (STN) 364. During initial training, the neural network 356 may receive the moving image 302 and the fixed image 304 as inputs. Thereafter, a parameter representation 322 based on one or more of: a rigid transform, an affine transform, a coordinate transform, and/or a deformable transformation may be output.

For example, the neural network 356 may be trained to provide an output that is parameterized with one or more of: dense displacement, basis spline (i.e., B-spline), or another parametric form. Furthermore, the parameter representation 322 may be a combination of the noted transforms, such as, for example: an affine+deformable transform, an affine+coordinate transform, and/or a coordinate+deformable transform.

In some implementations, the parameter representation 322 may be a vector of length n corresponding to the associated transformation parameters.

The parameter representation 322 may be converted, at conversion layer 324, by converting parameters of the n-length vector into another dense displacement field. For example, given the output parameters of parameter representation 322, the conversion layer 324 may generate a “transformation” matrix that may describe how each pixel of the moving image 302 may be mapped to a new location.

The alternate registration component 358 may provide the transformation matrix as input to the STN 364, which may also receive the moving image 302. The STN 364 may apply the transformation matrix to the moving image 302 and may output a deformed moved image 366.

A loss value may be calculated based upon the deformed moved image 366 and the input images 302, 304, such that one or more parameters of the neural network 356 may be adjusted to minimize a loss function. The loss function used in training the alternative registration component 358 may include any of the loss functions described above. Other loss functions may also be applicable.

The trained neural network 356 may be deployed for image registration with an imaging device, in some implementations. The alternative registration component 358 may provide the transformation matrix output from the conversion layer 324 as input to the STN 364, which may also receive the moving image 302. The STN 364 may apply the transformation matrix to the moving image 302 and may output the deformed moved image 366. The trained neural network 356 of alternative registration component 358 may provide a parameter representation 322 as an output for registering the moving image 302 to the fixed image 304.

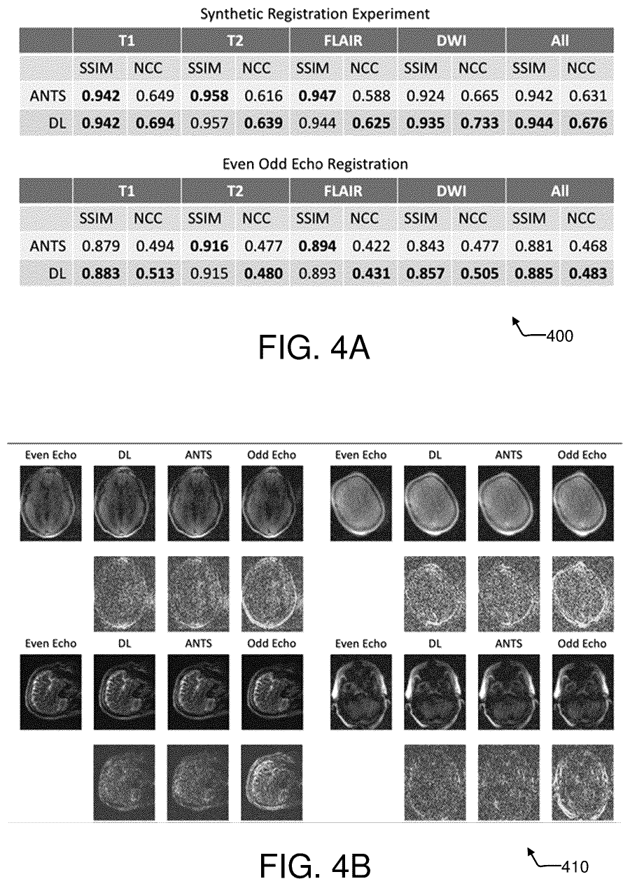

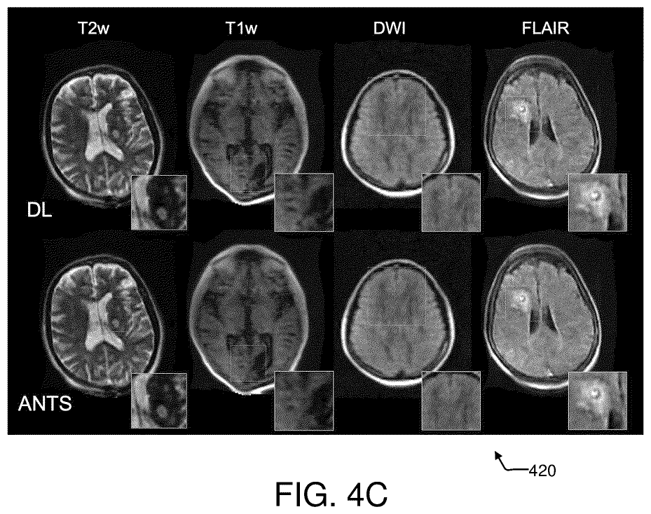

### FIG. 4: Experimental Results

FIG. 4A illustrates a table of quantitative experimental results of image registration with the trained neural network results being marked as “DL” and baseline methodology advanced normalization tools (ANTS). As illustrated, one can observe that overall DL outperformed the baseline method ANTS. The improvement in LNCC was also notable for T1-weighted, FLAIR and DWI images.

FIG. 4B illustrates a comparison of qualitative experimental results of image registration. The overall performances of the two approaches were comparable. However, ANTS occasionally failed to completely register small local features. While in general, both registrations worked well globally, (top left) ANTS missed to fully register within mid-brain region, (bottom left) ANTS have some blurring of the structure that was mitigated in the DL, (top right) ANTS was less smooth in regions and (bottom right) ANTS missed low-SNR region whereas this is improved in the DL.

FIG. 4C illustrates a comparison of qualitative experimental results of pathology images, and depicts the outputs of the reconstruction pipeline 20. As shown, DL particularly improves upon ANTS in terms of sharpness. FIG. 4C highlights the region-of-interest containing pathology and/or small features, in which the proposed DL approach preserved the details and were consistent with ANTS. Overall, the proposed DL approach had better sharpness across the images and across all contrasts.

As described above, an image acquisition application and image registration application may provide a pipeline that provides results that overcome drawbacks associated with generic and conventional MR imaging practices. In particular, better image quality and faster scan times can be achieved without detriment to imaging quality.

Hereinafter, example methods of training and using neural networks associated with an image acquisition application and image registration application are described in detail.

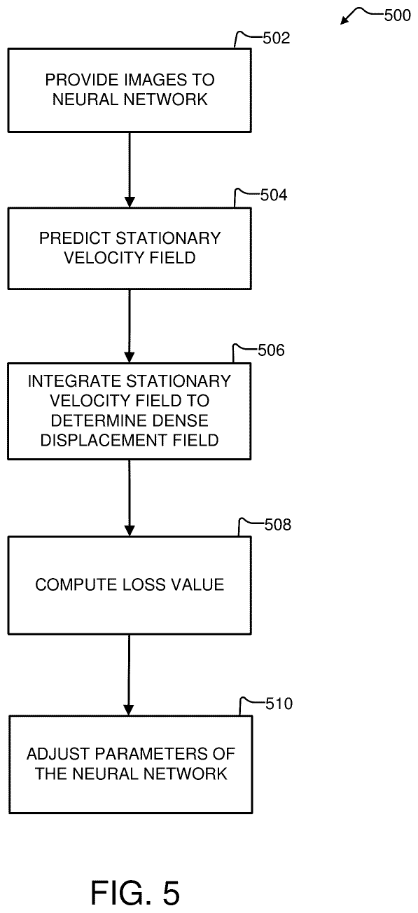

### FIG. 5: Method of Training a Neural Network

FIG. 5 is a flowchart of an example method 500 of unsupervised training of a neural network, in accordance with some implementations.

In some implementations, method 500 can be implemented, for example, on an imaging device. In some implementations, method 500 can be implemented, for example, in an imaging or training pipeline. In some implementations, method 500 may be implemented in a network environment arranged for training a neural network. In some implementations, some or all of the method 500 can be implemented on one or more client devices, or on one or more server device(s), and/or on a combination of imaging device(s), server device(s) and client device(s). In described examples, the implementing system includes one or more digital processors or processing circuitry (“processors”), and one or more storage devices. In some implementations, different components of one or more imaging devices and/or client devices can perform different blocks or other parts of the method 500. In some examples, a first device is described as performing blocks of method 500. Some implementations can have one or more blocks of method 500 performed by one or more other devices (e.g., other client devices or imaging devices) that can send results or data to the first device.

Method 500 may begin at block 502. At block 502, images may be provided to a neural network to be trained. For example, a sequence of existing FSE images may be provided to an untrained neural network. In at least one implementation, the first image and the second image may be reconstructed from a fast spin echo (FSE) magnetic resonance (MR) imaging sequence. Block 502 may be followed by block 504.

At block 504, a stationary velocity field may be predicted using the neural network. Block 504 may be followed by block 506.

At block 506, the stationary velocity field may be integrated to determine a dense displacement field. For example, by scaling and squaring layers of the stationary velocity field, with an integration layer, a dense displacement field may be obtained. In some implementations, the dense displacement field may be a diffeomorphic displacement field. Block 506 may be followed by block 508.

At block 508, a registration loss value may be computed based upon the input images and output image such that local normalized cross correlation (LNCC) is minimized. Other loss functions (e.g., L1, L2, L1+L2, etc.) may also be applicable in some implementations. Block 508 may be followed by block 510.

At block 510, one or more parameters of the neural network may be adjusted based on the registration loss value. In at least one implementation, the one or more parameters may be node weights of the neural network. In at least one implementation, the one or more parameters may be a number of layers of the neural network. Other parameters may also be applicable.

The method 500 may be repeated for a plurality of training images until the LNCC is minimized. The method 500 may be repeated for a plurality of training images until the neural network is trained. The trained network may be deployed in an imaging device, imaging pipeline, and/or network environment.

It is noted that blocks 502-510 can be performed (or repeated) in a different order than described above and/or one or more blocks can be omitted. For example, in one implementation, blocks 504-506 may be replaced with functionality associated with tan alternative registration component. In this example, the functionality may include obtaining, from the neural network, a parameter representation and obtaining, from a conversion layer, a transformation matrix based upon the parameter representation. A transformed image may be obtained through application of the transformation matrix by an STN.

Other alternative method blocks and operations may also be applicable. Furthermore, portions of the method 500 may be combined and performed in sequence or in parallel, according to any desired implementation.

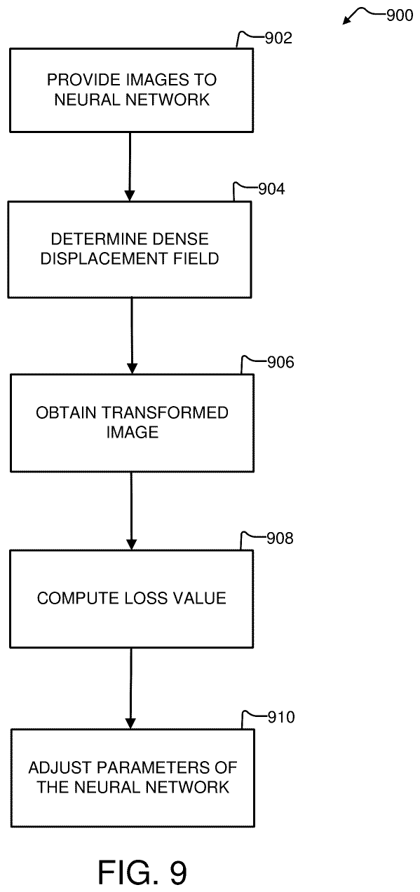

### FIG. 9: Method of Training a Neural Network

FIG. 9 is a flowchart of an example method 900 of unsupervised training of a neural network, in accordance with some implementations.

In some implementations, method 900 can be implemented, for example, on an imaging device. In some implementations, method 900 can be implemented, for example, in an imaging or training pipeline. In some implementations, method 900 may be implemented in a network environment arranged for training a neural network. In some implementations, some or all of the method 900 can be implemented on one or more client devices, or on one or more server device(s), and/or on a combination of imaging device(s), server device(s) and client device(s). In described examples, the implementing system includes one or more digital processors or processing circuitry (“processors”), and one or more storage devices. In some implementations, different components of one or more imaging devices and/or client devices can perform different blocks or other parts of the method 900. In some examples, a first device is described as performing blocks of method 900. Some implementations can have one or more blocks of method 900 performed by one or more other devices (e.g., other client devices or imaging devices) that can send results or data to the first device.

Method 900 may begin at block 902. At block 902, images may be provided to a neural network to be trained. For example, a sequence of existing FSE images may be provided to an untrained neural network. In at least one implementation, the first image and the second image may be reconstructed from a fast spin echo (FSE) magnetic resonance (MR) imaging sequence. Block 902 may be followed by block 904.

At block 904, a dense displacement field may be determined. For example, a dense displacement field may be obtained directly from a neural network. In some implementations, the dense displacement field is a diffeomorphic displacement field. Block 904 may be followed by block 906.

At block 906, a transformed image (which may also be referred to as a deformed moved image) may be obtained. The transformed image may be obtained by applying the dense displacement field to an input or moving image, in some implementations. Block 906 may be followed by block 908.

At block 908, a registration loss value may be computed based upon the input images and output image (e.g., the transformed image) such that local normalized cross correlation (LNCC) is minimized. Other loss functions (e.g., L1, L2, etc.) may also be applicable in some implementations. Block 908 may be followed by block 910.

At block 910, one or more parameters of the neural network may be adjusted based on the registration loss value. In at least one implementation, the one or more parameters may be node weights of the neural network. In at least one implementation, the one or more parameters may be a number of layers of the neural network. Other parameters may also be applicable.

The method 900 may be repeated for a plurality of training images until the LNCC is minimized. The method 900 may be repeated for a plurality of training images until the neural network is trained. The trained neural network may be deployed in an imaging device, imaging pipeline, and/or network environment.

It is noted that blocks 902-910 can be performed (or repeated) in a different order than described above and/or one or more blocks can be omitted. For example, in one implementation, blocks 904-906 may be replaced with functionality associated with an alternative registration component. In this example, the functionality may include obtaining, from the neural network, a parameter representation and obtaining, from a conversion layer, a transformation matrix based upon the parameter representation. A transformed image may be obtained through application of the transformation matrix by a STN.

Other alternative method blocks and operations may also be applicable. Furthermore, portions of the method 900 may be combined and performed in sequence or in parallel, according to any desired implementation.

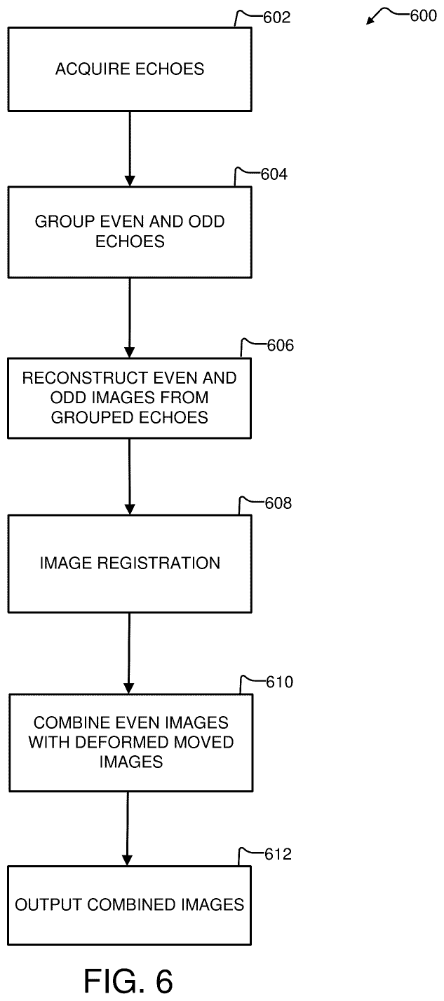

### FIG. 6: Method of Medical Imaging

FIG. 6 is a flowchart of a method 600 of medical imaging, in accordance with some implementations.

In some implementations, method 600 can be implemented, for example, on an imaging device. In some implementations, method 600 can be implemented, for example, in an imaging pipeline. In some implementations, some or all of the method 600 can be implemented on one or more client devices, or on one or more server device(s), and/or on a combination of imaging device(s), server device(s) and client device(s). In described examples, the implementing system includes one or more digital processors or processing circuitry (“processors”), and one or more storage devices. In some implementations, different components of one or more imaging devices and/or client devices can perform different blocks or other parts of the method 600. In some examples, a first device is described as performing blocks of method 600. Some implementations can have one or more blocks of method 600 performed by one or more other devices (e.g., other client devices or imaging devices) that can send results or data to the first device.

Method 600 may begin at block 602. At block 602, two or more echoes 210 may be acquired. For example, the echoes 210 may be acquired from imaging components of an MR imaging device. In some implementations, the echoes 210 may be acquired through an FSE technique on a portable MR imaging device. Block 602 may be followed by block 604.

At block 604, even and odd echoes may be grouped separately for reconstruction. For example, grouping may include separating even echoes from odd echoes such that processing and computations may be performed on even echoes and odd echoes separately. Block 604 may be followed by block 606.

At block 606, the even and odd echoes may be reconstructed separately into a plurality of even and odd echo images. For example, a reconstruction component may reconstruct both an even image and odd image from associated input echoes. Block 606 may be followed by block 608.

At block 608, the odd echo images may be registered to the even echo images. For example, the image registration may be performed by a registration component or an alternative registration component. Block 608 may be followed by block 610.

At block 610, even echo images may be combined with images output from a registration component (e.g., deformed moved images or transformed images). Block 610 may be followed by block 612.

At block 612, the combined images may be output as final images for further processing, display, and/or viewing by a medical professional.

It is noted that blocks 602-612 can be performed (or repeated) in a different order than described above and/or one or more blocks can be omitted. For example, block 608 may also include image registration of multiple images in addition to even and odd echoes. In this example, multiple images may be registered for motion compensation and other uses.

Other alternative method blocks and operations may also be applicable. Furthermore, portions of the method 600 may be combined and performed in sequence or in parallel, according to any desired implementation.

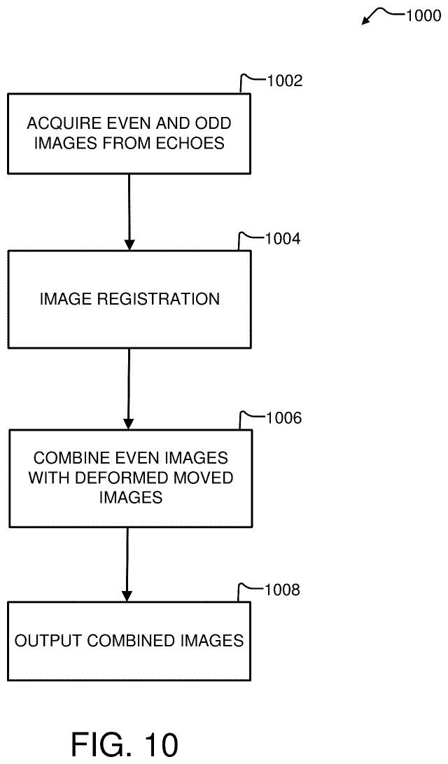

### FIG. 10: Method of Medical Imaging

FIG. 10 is a flowchart of a method 1000 of medical imaging, in accordance with some implementations.

In some implementations, method 1000 can be implemented, for example, on an imaging device. In some implementations, method 1000 can be implemented, for example, in an imaging pipeline. In some implementations, some or all of the method 1000 can be implemented on one or more client devices, or on one or more server device(s), and/or on a combination of imaging device(s), server device(s) and client device(s). In described examples, the implementing system includes one or more digital processors or processing circuitry (“processors”), and one or more storage devices. In some implementations, different components of one or more imaging devices and/or client devices can perform different blocks or other parts of the method 1000. In some examples, a first device is described as performing blocks of method 1000. Some implementations can have one or more blocks of method 1000 performed by one or more other devices (e.g., other client devices or imaging devices) that can send results or data to the first device.

Method 1000 may begin at block 1002. At block 1002 even and odd echo images may be acquired from a plurality of even and odd echoes. For example, a reconstruction component may reconstruct both an even image and odd image from associated input echoes. Block 1002 may be followed by block 1004.

At block 1004, the odd echo images may be registered to the even echo images. For example, the image registration may be performed by a registration component or an alternative registration component. Block 1004 may be followed by block 1006.

At block 1006, even echo images may be combined with images output from a registration component (e.g., deformed moved images or transformed images). Block 1006 may be followed by block 1008.

At block 1008, the combined images may be output as final images for further processing, display, and/or viewing by a medical professional.

It is noted that blocks 1002-1008 can be performed (or repeated) in a different order than described above and/or one or more blocks can be omitted. For example, block 1004 may also include image registration of multiple images in addition to even and odd echoes. In this example, multiple images may be registered for motion compensation and other uses.

Other alternative method blocks and operations may also be applicable. Furthermore, portions of the method 1000 may be combined and performed in sequence or in parallel, according to any desired implementation.

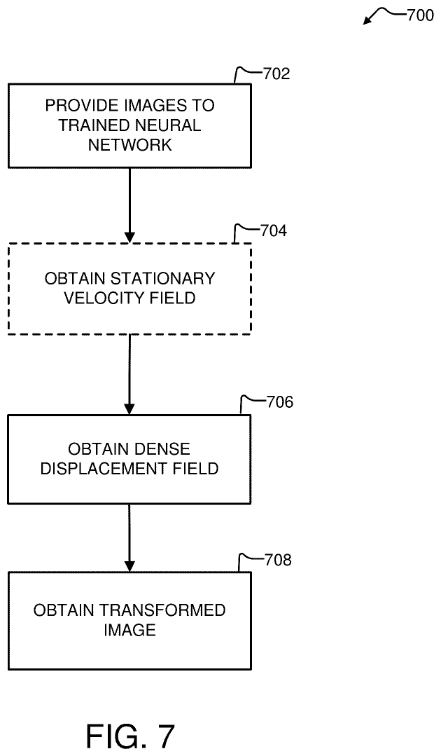

### FIG. 7: Method of Image Registration

FIG. 7 is a flowchart of a method 700 of image registration using a trained neural network, in accordance with some implementations.

In some implementations, method 700 can be implemented, for example, on an imaging device. In some implementations, method 700 can be implemented, for example, in an imaging pipeline. In some implementations, some or all of the method 700 can be implemented on one or more client devices, or on one or more server device(s), and/or on a combination of imaging device(s), server device(s) and client device(s). In described examples, the implementing system includes one or more digital processors or processing circuitry (“processors”), and one or more storage devices. In some implementations, different components of one or more imaging devices and/or client devices can perform different blocks or other parts of the method 700. In some examples, a first device is described as performing blocks of method 700. Some implementations can have one or more blocks of method 700 performed by one or more other devices (e.g., other client devices or imaging devices) that can send results or data to the first device.

Method 700 may begin at block 702. At block 702, a first image and a second image may be provided as input to a trained neural network. The first image and the second image may be images reconstructed from a fast spin echo (FSE) magnetic resonance (MR) imaging sequence, in some implementations. Block 702 may be followed by block 704.

At block 704, a stationary velocity field may be obtained as an output from the trained neural network. For example, the stationary velocity field may be a direct output of the trained neural network, in some implementations. Block 704 may be followed by block 706.

At block 706, a dense displacement field may be obtained either from the trained neural network directly (e.g., by omitting block 704) or by integrating the stationary velocity field with an integration layer. In some implementations, the dense displacement field may be a diffeomorphic displacement field. Block 706 may be followed by block 708.

At block 708, a transformed image may be obtained by applying the dense displacement field to the first image with a spatial transform network (STN). Corresponding features of the transformed image and the second image may be aligned. The transformed image (also referred to as a deformed moved image) may be provided as input to an image registration application for creation of a final image.

It is noted that blocks 702-708 can be performed (or repeated) in a different order than described above and/or one or more blocks can be omitted. For example, in one implementation, blocks 704 may be omitted and a dense displacement field may be output by the trained neural network directly.

In one implementation, blocks 704-706 may be replaced with functionality associated with an alternative registration component. In this example, the functionality may include obtaining, from the trained neural network, a parameter representation and obtaining, from a conversion layer, a transformation matrix based upon the parameter representation. A transformed image may be obtained through application of the transformation matrix by a STN at block 708.

Other alternative method blocks and operations may also be applicable. Furthermore, portions of the method 700 may be combined and performed in sequence or in parallel, according to any desired implementation.

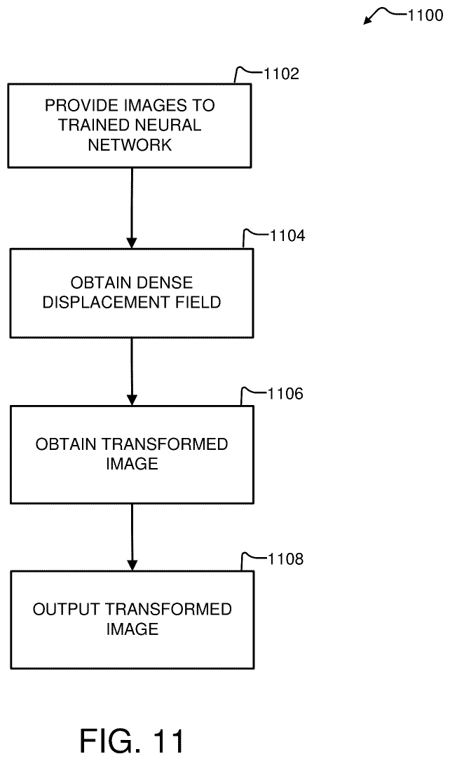

### FIG. 11: Method of Image Registration

FIG. 11 is a flowchart of a method 1100 of image registration using a trained neural network, in accordance with some implementations.

In some implementations, method 1100 can be implemented, for example, on an imaging device. In some implementations, method 1100 can be implemented, for example, in an imaging pipeline. In some implementations, some or all of the method 1100 can be implemented on one or more client devices, or on one or more server device(s), and/or on a combination of imaging device(s), server device(s) and client device(s). In described examples, the implementing system includes one or more digital processors or processing circuitry (“processors”), and one or more storage devices. In some implementations, different components of one or more imaging devices and/or client devices can perform different blocks or other parts of the method 1100. In some examples, a first device is described as performing blocks of method 1100. Some implementations can have one or more blocks of method 1100 performed by one or more other devices (e.g., other client devices or imaging devices) that can send results or data to the first device.

Method 1100 may begin at block 1102. At block 1102, a first image and a second image may be provided as input to a trained neural network. The first image and the second image may be images reconstructed from a fast spin echo (FSE) magnetic resonance (MR) imaging sequence, in some implementations. Block 1102 may be followed by block 1104.

At block 1104, a dense displacement field may be obtained from the trained neural network. In some implementations, the dense displacement field may be a diffeomorphic displacement field. Block 1104 may be followed by block 1106.

At block 1106, a transformed image may be obtained by applying the dense displacement field to the first image with a spatial transform network (STN). Corresponding features of the transformed image and the second image may be aligned. The transformed image (also referred to as a deformed moved image) may be provided as input to an image registration application for creation of a final image. Block 1106 may be followed by block 1108.

At block 1108, the transformed image may be output.

It is noted that blocks 1102-1108 can be performed (or repeated) in a different order than described above and/or one or more blocks can be omitted. In one implementation, blocks 1104-1106 may be replaced with functionality associated with an alternative registration component. In this example, the functionality may include obtaining, from the trained neural network, a parameter representation and obtaining, from a conversion layer, a transformation matrix based upon the parameter representation. A transformed image may be obtained through application of the transformation matrix by a STN at block 1106.

Other alternative method blocks and operations may also be applicable. Furthermore, portions of the method 1100 may be combined and performed in sequence or in parallel, according to any desired implementation.

### Example Computing Devices

Hereinafter, a more detailed description of various computing devices that may be used to implement different devices and/or components is provided with reference to FIG. 8.

FIG. 8 is a block diagram of an example computing device 800 which may be used to implement one or more features described herein, in accordance with some implementations. In one example, device 800 may be used to implement at least a portion of a computer device, and perform appropriate operations as described herein. Computing device 800 can be any suitable computer system, server, or other electronic or hardware device. For example, the computing device 800 can be a mainframe computer, desktop computer, workstation, portable computer, or electronic device. In some implementations, device 800 includes a processor 802, a memory 804, input/output (I/O) interface 806, and audio/video input/output devices 814 (e.g., display screen, touchscreen, display goggles or glasses, audio speakers, headphones, microphone, etc.).

Processor 802 can be one or more processors and/or processing circuits to execute program code and control basic operations of the device 800. A “processor” includes any suitable hardware and/or software system, mechanism or component that processes data, signals or other information. A processor may include a system with a general-purpose central processing unit (CPU), multiple processing units, dedicated circuitry for achieving functionality, or other systems. Processing need not be limited to a particular geographic location, or have temporal limitations. For example, a processor may perform its functions in “real-time,” “offline,” in a “batch mode,” etc. Portions of processing may be performed at different times and at different locations, by different (or the same) processing systems. A computer may be any processor in communication with a memory.

Memory 804 is typically provided in device 800 for access by the processor 802, and may be any suitable processor-readable storage medium, e.g., random access memory (RAM), read-only memory (ROM), Electrical Erasable Read-only Memory (EEPROM), Flash memory, etc., suitable for storing instructions for execution by the processor, and located separate from processor 802 and/or integrated therewith. Memory 804 can store software operating on the server device 800 by the processor 802, including an operating system 808, software application 810 and associated data 812. In some implementations, the applications 810 can include instructions that enable processor 802 to perform the functions described herein. Software application 810 may include some or all of the functionality required to process and register images, as described herein. In some implementations, one or more portions of software application 810 may be implemented in dedicated hardware such as an application-specific integrated circuit (ASIC), a programmable logic device (PLD), a field-programmable gate array (FPGA), a machine learning processor, etc. In some implementations, one or more portions of software application 810 may be implemented in general purpose processors, such as a central processing unit (CPU) or a graphics processing unit (GPU). In various implementations, suitable combinations of dedicated and/or general purpose processing hardware may be used to implement software application 810.

For example, software application 810 stored in memory 804 can include instructions for acquiring echo images or echo data, reconstructing images from echo data, registering reconstructed images, and or other imaging techniques and processes described herein. Any of software in memory 804 can alternatively be stored on any other suitable storage location or computer-readable medium. In addition, memory 804 (and/or other connected storage device(s)) can store instructions and data used in the features described herein. Memory 804 and any other type of storage (magnetic disk, optical disk, magnetic tape, or other tangible media) can be considered “storage” or “storage devices.”

I/O interface 806 can provide functions to enable interfacing the server device 800 with other systems and devices. For example, network communication devices, storage devices (e.g., memory and/or data store 108), and input/output devices can communicate via interface 806. In some implementations, the I/O interface can connect to interface devices including input devices (keyboard, pointing device, touchscreen, microphone, camera, scanner, etc.) and/or output devices (display device, speaker devices, printer, motor, etc.).

For case of illustration, FIG. 8 shows one block for each of processor 802, memory 804, I/O interface 806, software blocks 808 and 810, and database 812. These blocks may represent one or more processors or processing circuitries, operating systems, memories, I/O interfaces, applications, and/or software modules. In other implementations, device 800 may not have all of the components shown and/or may have other elements including other types of elements instead of, or in addition to, those shown herein.

A user device can also implement and/or be used with features described herein. Example user devices can be computer devices including some similar components as the device 800, e.g., processor(s) 802, memory 804, and I/O interface 806. An operating system, software and applications suitable for the client device can be provided in memory and used by the processor. The I/O interface for a client device can be connected to network communication devices, as well as to input and output devices, e.g., a microphone for capturing sound, a camera for capturing images or video, audio speaker devices for outputting sound, a display device for outputting images or video, or other output devices. A display device within the audio/video input/output devices 814, for example, can be connected to (or included in) the device 800 to display images pre- and post-processing as described herein, where such display device can include any suitable display device, e.g., an LCD, LED, or plasma display screen, CRT, television, monitor, touchscreen, 3-D display screen, projector, or other visual display device. Some implementations can provide an audio output device.

The methods, blocks, and/or operations described herein can be performed in a different order than shown or described, and/or performed simultaneously (partially or completely) with other blocks or operations, where appropriate. Some blocks or operations can be performed for one portion of data and later performed again, e.g., for another portion of data. Not all of the described blocks and operations need be performed in various implementations. In some implementations, blocks and operations can be performed multiple times, in a different order, and/or at different times in the methods.

In some implementations, some or all of the methods can be implemented on a system such as one or more client devices. In some implementations, one or more methods described herein can be implemented, for example, on a server system, and/or on both a server system and a client system. In some implementations, different components of one or more servers and/or clients can perform different blocks, operations, or other parts of the methods.

One or more methods described herein can be implemented by computer program instructions or code, which can be executed on a computer. For example, the code can be implemented by one or more digital processors (e.g., microprocessors or other processing circuitry), and can be stored on a computer program product including a non-transitory computer readable medium (e.g., storage medium), e.g., a magnetic, optical, electromagnetic, or semiconductor storage medium, including semiconductor or solid state memory, magnetic tape, a removable computer diskette, a random access memory (RAM), a read-only memory (ROM), flash memory, a rigid magnetic disk, an optical disk, a solid-state memory drive, etc. The program instructions can also be contained in, and provided as, an electronic signal, for example in the form of software as a service (SaaS) delivered from a server (e.g., a distributed system and/or a cloud computing system). Alternatively, one or more methods can be implemented in hardware (logic gates, etc.), or in a combination of hardware and software. Example hardware can be programmable processors (e.g. Field-Programmable Gate Array (FPGA), Complex Programmable Logic Device), general purpose processors, graphics processors, Application Specific Integrated Circuits (ASICs), and the like. One or more methods can be performed as part of or component of an application running on the system, or as an application or software running in conjunction with other applications and operating system.

One or more methods described herein can be run in a standalone program that can be run on any type of computing device, a program run on a web browser, or a mobile application (“app”) executing on a mobile computing device.

In situations in which certain implementations discussed herein may obtain or use user data (e.g., user images, user medical data, user contextual data, etc.) users are provided with options to control whether and how such information is collected, stored, or used. That is, the implementations discussed herein collect, store and/or use user information upon receiving explicit user authorization and in compliance with applicable regulations.

Users are provided with control over whether programs or features collect user information about that particular user or other users relevant to the program or feature. Each user for which information is to be collected is presented with options (e.g., via a user interface) to allow the user to exert control over the information collection relevant to that user, to provide permission or authorization as to whether the information is collected and as to which portions of the information are to be collected. In addition, certain data may be modified in one or more ways before storage or use, such that personally identifiable information is removed. As one example, a user's identity may be modified (e.g., by substitution using a pseudonym, numeric value, etc.) so that no personally identifiable information can be determined. In another example, a user's geographic location may be generalized to a larger region (e.g., city, zip code, state, country, etc.).

Although the description has been described with respect to particular implementations thereof, these particular implementations are merely illustrative, and not restrictive. Concepts illustrated in the examples may be applied to other examples and implementations.

Note that the functional blocks, operations, features, methods, devices, and systems described in the present disclosure may be integrated or divided into different combinations of systems, devices, and functional blocks as would be known to those skilled in the art. Any suitable programming language and programming techniques may be used to implement the routines of particular implementations. Different programming techniques may be employed, e.g., procedural or object-oriented. The routines may execute on a single processing device or multiple processors. Although the steps, operations, or computations may be presented in a specific order, the order may be changed in different particular implementations. In some implementations, multiple steps or operations shown as sequential in this specification may be performed at the same time.

What is claimed is:

1. A computer-implemented method to train a neural network to perform image registration, the method comprising:
providing as input to the neural network, a first image and a second image, wherein the first image and the second image are reconstructed from a fast spin echo (FSE) magnetic resonance (MR) imaging sequence;
determining, using the neural network, a dense displacement field based at least on the first image and the second image;
obtaining, using the neural network, a transformed image based on the first image and the dense displacement field, wherein the transformed image is aligned with the second image;
computing a registration loss value based on comparison of the transformed image and the second image; and
adjusting one or more parameters of the neural network based on the registration loss value.

2. The computer-implemented method of claim 1, wherein determining the dense displacement field comprises:
predicting, using the neural network, a stationary velocity field; and
integrating, using the neural network, the stationary velocity field to determine the dense displacement field.

3. The computer-implemented method of claim 1, wherein the dense displacement field is a diffeomorphic displacement field.

4. The computer-implemented method of claim 1, wherein the first image is reconstructed from a first set of echoes of the FSE MR imaging sequence, and wherein the second image is reconstructed from a second set of echoes of the FSE MR imaging sequence.

5. The computer-implemented method of claim 1, wherein obtaining the transformed image comprises:
applying, with a spatial transform network, the dense displacement field to the first image, wherein the spatial transform network outputs the transformed image.

6. The computer-implemented method of claim 1, wherein computing the registration loss value comprises:
minimizing a local normalized cross correlation value based on the transformed image and the second image.

7. The computer-implemented method of claim 1, wherein training the neural network is an unsupervised process.

8. A device to perform image registration, the device comprising:
one or more processors; and
a memory coupled to the one or more processors, with instructions stored thereon that, when executed by the processor, cause the one or more processors to perform operations comprising:
providing a first image and a second image as input to a trained neural network, wherein the first image and the second image are reconstructed from a fast spin echo (FSE) magnetic resonance (MR) imaging sequence;
obtaining, as output of the trained neural network, a dense displacement field for the first image;
obtaining a transformed image by applying the dense displacement field to the first image with a spatial transform network, wherein corresponding features of the transformed image and the second image are aligned; and
outputting the transformed image.

9. The device of claim 8, wherein obtaining the dense displacement field comprises:
obtaining, using the trained neural network, a stationary velocity field; and
integrating, using the trained neural network, the stationary velocity field to determine the dense displacement field.

10. The device of claim 8, wherein the device is a portable low-field MR imaging device having a display device and at least one permanent magnet.

11. The device of claim 10, wherein the first image is reconstructed from a first set of echoes of the FSE MR imaging sequence, and wherein the second image is reconstructed from a second set of echoes of the FSE MR imaging sequence.

12. The device of claim 11, wherein the first set of echoes comprise odd echoes, and wherein the second set of echoes comprises even echoes.

13. The device of claim 12, wherein the first image and the second image are of a human tissue or a human organ.

14. The device of claim 13, wherein outputting the transformed image comprises displaying the transformed image on the display device.

15. A non-transitory computer-readable medium to train a neural network to perform image registration with instructions stored thereon that, when executed by a processor of a server, cause the processor to perform operations, the operations comprising:
providing as input to the neural network, a first image and a second image, wherein the first image and the second image are reconstructed from a fast spin echo (FSE) magnetic resonance (MR) imaging sequence;
determining, using the neural network, a dense displacement field based at least on the first image and the second image;
obtaining, using the neural network, a transformed image based on the first image and the dense displacement field, wherein the transformed image is aligned with the second image;
computing a registration loss value based on comparison of the transformed image and the second image; and
adjusting one or more parameters of the neural network based on the registration loss value.

16. The non-transitory computer-readable medium of claim 15, wherein determining the dense displacement field comprises:
predicting, using the neural network, a stationary velocity field; and
integrating, using the neural network, the stationary velocity field to determine the dense displacement field.

17. The non-transitory computer-readable medium of claim 15, wherein the first image is reconstructed from a first set of echoes of the FSE MR imaging sequence, and wherein the second image is reconstructed from a second set of echoes of the FSE MR imaging sequence.

18. The non-transitory computer-readable medium of claim 15, wherein obtaining the transformed image comprises:
applying, with a spatial transform network, the dense displacement field to the first image, wherein the spatial transform network outputs the transformed image.

19. The non-transitory computer-readable medium of claim 15, wherein computing the registration loss value comprises:
minimizing a local normalized cross correlation value based on the transformed image and the second image.

20. The non-transitory computer-readable medium of claim 15, wherein training the neural network is an unsupervised process.
